(19) United States
(12) Patent Application Publication
(10) Pub. No.: US 2003/0156724 A1
(43) Pub. Date: Aug. 21, 2003

(54) Pill, capsule, or medicine container audio instruction systems and methods for providing audio instructions with pill, capsule, or medicine containers

(75) Inventors: Anthony R. Mariano, Albany, NY (US); Randy L. Allnatt, Albany, NY (US)

Correspondence Address: Victor A. Cardona, Nicholas Mesiti, Heslin Rothenberg Farley & Mesiti P.C., 5 Columbia Circle, Albany, NY, 12203, US

(73) Assignee: Medivox RX Technologies, Inc., Albany, NY

(21) Appl. No.: 10/080,285

(22) Filed: Feb. 21, 2002

(51) Int. Cl. G07F 11/00; H03G 3/00; H04B 1/00; G10L 11/00; G10L 21/00

(52) U.S. Cl. 381/124; 381/61; 221/3; 704/272

(57) ABSTRACT

An audio instruction system includes a pill container, a sound player, an activating member, and a locator. The sound player is operatively engaged to the pill container. The activating member is operatively engaged to the pill container to activate the sound player. The locator is positioned relative to the pill container and the activating member to aid a user to locate the activating member.

### TECHNICAL FIELD

This invention relates in general to pill, capsule, tablet, and medicine containers and more specifically to an apparatus and method for aiding the visually impaired identify the contents and directions of use for a product stored in such a container.

### BACKGROUND ART

Standard product labels currently present product information on contents, usage and instructions in print form only on the label attached to the container. While printed instructions on a label for a container are a satisfactory method of informing the user what it is and how to use it, such instructions in print form only on a label present significant problems for persons with visual impairments, especially when the product is a prescription medication. Therefore, there is a need to provide these persons with the vital product instructions they need while insuring them the personal dignity they deserve.

Presently, there are many different types of devices in order to assist visually impaired persons in the administration of products, especially for prescription drugs. For example, U. S. Pat. No. 5,812,064 to Barbour for a medicine container with a voice sound conveyor provides a medicine container with a voice sound conveyor that will play back the audio instructions for the medicine container on a reader which the patient must purchase in order to access the information. The visual impaired person must purchase an expensive playback unit in order to access the audio instructions. Also, this device contains a speech memory unit which is designed to be erasable and the visually impaired person is required to reuse the device.

U.S. Pat. No. 5,835,455 to Hanson et al. for an audio prescription instruction device discloses a reprogrammable device for housing a medication container for playing audio instructions on the medication container. Although this device discloses a self-contained unit for audio instructions on the bottle, the device has a recording mechanism on the bottle and may be erased by the visually impaired person. Also, the playback unit must be reprogrammed and reused for each medication that the visually impaired person receives.

U.S. Pat. No. 5,846,089 to Weiss et al. for a medicine container indicating patient information discloses a medicine container containing audio instructions. However, this container is designed to be programmed and reprogrammed by the user or someone familiar with the user. Therefore, it is dependent on the ability of the user to be able to program the device or reprogram it if the instructions are accidentally or intentionally erased. Since the audible dosage instructions are erasable at the whim of the visually impaired person, this device does not properly address the needs of a visually impaired person who is unable to remember the instructions after they are erased.

Finally, U.S. Pat. No. 5,852,803 to Ashby for an apparatus, system and method for recording and/or retrieving audio information discloses a reusable label for a prescription container having audio instructions. However, this invention requires the visually impaired person to reuse the label. Also, the visually impaired person has the capacity to alter or erase the audio instructions. Finally, the label itself may become detached from the container itself which would render the audio instructions meaningless.

All of the above devices overlook the problem associated with visual impairment, namely that the visually impaired person may accidentally erase and reprogram the instructions on the above devices. This could be disastrous for the visually impaired person. Also, the above devices must be reprogrammed for each refill. This may be inconvenient for the visually impaired person to have to send the device out to be reprogrammed with new instructions.

Another problem associated with prior art is that the devices have parts that are not water-resistant to normal usage such as microphones which can be contaminated and rendered inoperable through normal living events such as food spillage.

Further, the devices described above are adapted to aid a visually impaired user by utilizing sound to convey information thereto. However, to access this sound information, it is necessary for the visually impaired user to activate the sound producing portion of device. To accomplish this, the user must locate the means for activating the sound which may be difficult since the user cannot locate this activator through visual means.

Therefore, it is desirable to have a product container that has audio instructions permanently affixed to the container, which is for a single use and may not be accidently erased. There is also a need for a device that does not require the purchase of significant equipment and is economical for the visually impaired person. Also, there is a need for the device to have exposed parts that are water resistant so that the parts do not get contaminated from normal, everyday living. Further, there is a need for a device which aids the visually impaired user in locating the means for activating the device.

### SUMMARY OF THE INVENTION

The present invention provides, in a first aspect, an audio instruction system. The system includes a pill container, a sound player, an activating member, and a locator. The sound player is operatively engaged to the pill container and the activating member is operatively engaged to the pill container to activate the sound player. The locator is positioned relative to the pill container and the activating member to aid a user to locate the activating member.

The present invention provides, in a second aspect, a method for providing audio instructions to a user of medication. The method includes positioning a locator on a pill container of the audio instruction device and feeling the locator to find an activating member for activating a sound player of the audio instruction device.

The present invention provides, in a third aspect, a method for providing audio instructions to a user of medication. The method includes engaging a locator of an audio instruction device with a receiving slot of an audio instruction sending unit.

The present invention provides, in a fourth aspect, a method for providing audio instructions. The method includes providing a pill container and operatively engaging a sound player to the pill container. Further, the method includes operatively engaging a sound player to the pill container. Yet further, the method includes operatively engaging an activating member for activating the sound player to the pill container and positioning a locator relative to the pill container and the activating member to aid a user to locate the activating member.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention will be readily understood from the following detailed description of preferred embodiments taken in conjunction with the accompanying drawings in which:

FIG. 1 is a side elevational view of an audio instruction device, in accordance with present invention;

FIG. 2 is an exploded view of the audio instruction device of FIG. 1;

FIG. 3 is a perspective view of a cap of the audio instruction device of FIG. 1;

FIG. 4 is a side elevational view of a recorder unit adapted to engage the audio instruction device of FIG. 1;

FIG. 5 is a top elevational view of the recorder unit of FIG. 4;

FIG. 6 is a perspective view of a door of a housing of the audio instruction device of FIG. 1;

FIG. 7 is a bottom elevational view of the audio instruction device of FIG. 1;

FIG. 8 is a side elevational view of a locking member and an outer surface of the audio instruction device of FIG. 1;

FIG. 9 is a perspective view of another embodiment of an audio instruction device in accordance with the present invention; and

FIG. 10 is an example of a recorder unit adapted to engage the audio instruction device of FIG. 9, in accordance with the present invention.

### DETAILED DESCRIPTION

In accordance with the principles of the present invention, audio instruction systems and methods for providing audio instructions to a user are provided.

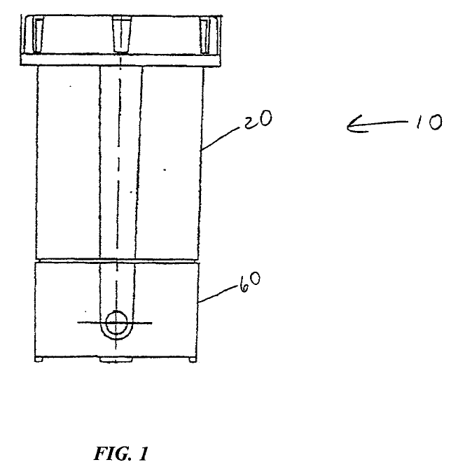

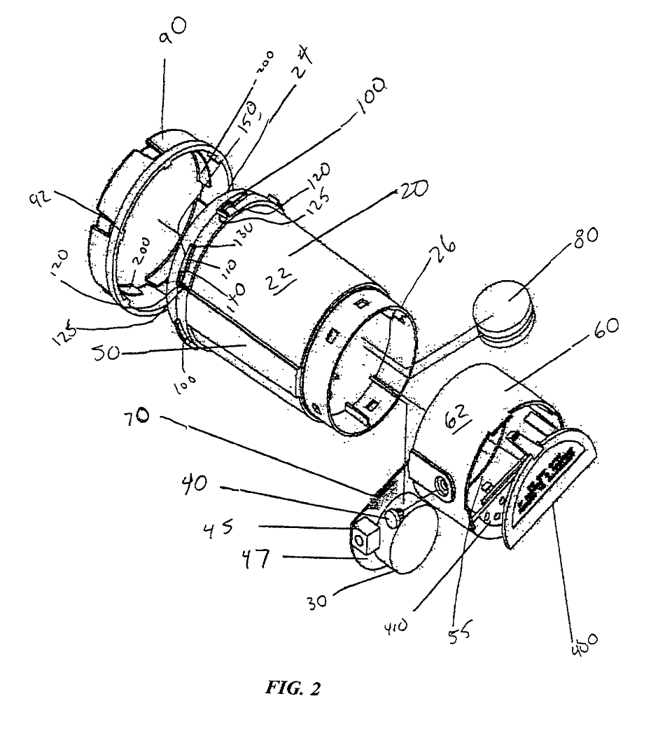

In an exemplary embodiment depicted in FIGS. 1-2, an audio instruction system 10 includes a pill container 20, a sound player 30, an activating member 40, and a locator 50. Container 20 may hold pills, tablets, capsules or other means of ingesting prescription drugs, non-prescription drugs, vitamins, or nutritional supplements, for example. Sound player 30 may be adapted to play audio instructions relating to the use of medicine held in container 20. Locator 50 may be formed in container 20 to facilitate a visually impaired person in finding activating member 40.

In one example, locator 50 may be a locating ridge formed on an outer surface 22 of container 20 to allow a visually impaired person to tactilely locate activating member 40. Specifically, the visually impaired person may easily find locator 50 because of its raised profile compared to the remainder of container 20 and due to its presence over a substantial portion of outer surface 22. For example, locator 50 may be aligned substantially longitudinally along outer surface 22. Thus, the user may easily locate locator 50 by touch and he may then feel along locator 50 to find activating member 40, which may be aligned with locator 50 or may be received in an aperture of locator 50 or formed integral thereto.

Alternatively, locator 50 could be a depression or other irregularity in outer surface 22 of container 20 or system 10 which allows one navigating by touch to locate activating member 40. Further, activating member 40 may be a button or other means of causing sound player 30 to produce voice instructions relating to the medicine held in container 20. Activating member 40 may be a different texture or at a different height relative to surface 22 than locator 50. Such differences facilitate the user in easily differentiating between locator 50 and activating member 40 to allow the user to locate activating member 40. Sound player 30 may be a speaker or other means of playing such voice instructions.

Container 20 may be mounted to a housing 60 which houses sound player 30 along with electronic components associated therewith. Specifically, housing 50 includes an interior portion 55 which contains sound player 30 coupled to a microchip (not shown) and an interface port 70. Further included is a button interface 45 coupled to activating member 40. Button interface 45 may be adapted to interface with the microchip to cause sound player 30 to play voice instructions previously saved on the microchip in response to activation of activating member 40 by the user. Interface port 70 is coupled to the microchip and is adapted to receive voice instruction information from an external source. For example, interface port 70 may be a 6-pin port adapted to receive a corresponding interface device, such as a computer cable or an interface port of a data-sending device, for example, a recorder unit 300 (FIG. 4).

Further included in interior 55 may be a battery 80 coupled to the microchip, sound player 30, and/or button interface 45, as will be understood by those skilled in the art. A circuit board 47 may also be included in housing 60 to hold or align some of the various electronic components, microchip, and/or sound player 30, as will be understood by those skilled in the art. The microchip could be a “voice chip” playback device such as Part No. ISD 1420 from Information Storage Devices, Inc., for example. This microchip may yield 20 seconds of embedded speech. Alternatively, the microchip could be Part No. ISD 2532, which may yield 32 seconds of embedded speech. Also, it will be understood by those skilled in the art that voice instruction information or other sound information might be stored on any electronic storage device adapted to store sound information. Further, it will be understood by those skilled in the art that sound player 30 could include an electronic storage portion capable of storing voice instruction information, an interface port for receiving voice instruction information from an external source and/or a microprocessor to power a speaker integral thereto.

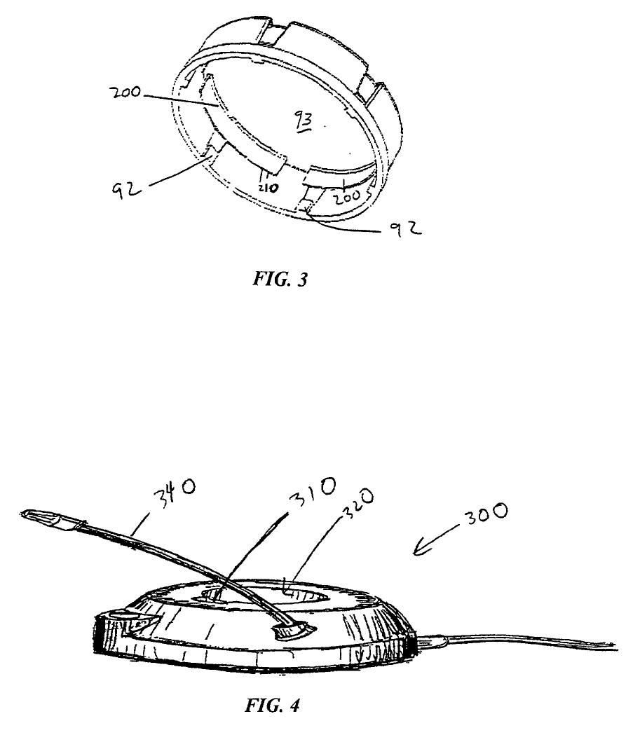

As is evident from FIGS. 1-2, locator 50 may extend from container 20 to housing 60. Also, activating member 40 may be located on an outside surface 62 of housing 60 and may extend therethrough to engage button interface 45. Further included on an outside surface 22 of container 20 may be bayonet locking members 100 adapted to receive radially projecting members 92 (FIGS. 2-3) of cap 90, as depicted in FIGS. 1, 2, and 8. As will be evident to those skilled in the art, child resistant properties are provided by engagement of projecting members 92 with locking members 100. Specifically, locking members 100 include an angled flange 110 having a flat opening-preventing side 120, and a rotation-stopping surface 125. Angled flange 110 includes a first end 130 and a second end 140 wherein angled flange 110 increases in dimension from first end 130 to second end 140 and wherein a top end 150 remains at a substantially constant distance from a top 24 of container 20.

Thus, as cap 90 is turned clockwise, projecting members 92 pass along angled flanges 110 and are drawn toward a bottom end 26 of container 20, as projecting members 92 pass from first end 130 to second end 140. When projecting members 92 pass angled flange 110, they may move toward a top end 24 of container 20 and projecting members 92 may abut flat opening-preventing side 120. Thus, projecting members 92 may be inhibited from rotating in a counter-clockwise direction by flat opening-preventing side 120 due to projecting members 92 having moved toward top 24 of container 20, as will be understood by those skilled in the art. Further, projecting members 92 may be inhibited from rotating in a clockwise direction by rotation-stopping surface 125. Therefore, to open cap 90, it is necessary to push cap 90, and thus projecting members 92, toward a bottom 26 of container 20 to allow projecting members 92 to be rotated in a counter clockwise direction past second end 140 of angled flange 110 and thus flat opening-preventing side 120. Cap 90 may then be pulled off container 20.

Further, inner ribs 200 of cap 90 inhibit movement of cap 90 toward bottom 26, as best depicted in FIGS. 2-3. Inner ribs 200 are spaced from one another and attached to an inner bottom surface 93 of cap 90. Also, inner ribs 200 are adapted to engage outer surface 22 and pass top 24 of container 20. Specifically, bottom ends 210 of inner ribs 200 are adapted to engage outer surface 22, and inner ribs 210 are adapted to elastically deflect radially outwardly as cap 90 engages container 20. This elastic nature allows inner ribs 200 to store energy when cap 90 is attached to container 20 via projecting members 92 and locking members 100. Outer surface 22 may be formed in a conical shape with a smallest diameter at top 24. This shape facilitates passing of inner ribs 200 past top 24 while facilitating the storing of energy by inner ribs 200 as bottom ends 210 pass further along outer surface 22. Thus, when projecting members 92 are released from locking members 100, this stored energy promotes release of cap 90 from container 20 in a direction away from container 20. Thus, inner ribs 200 may make it easier for a user to remove cap 90 from container 20 when projecting members 92 are released therefrom.

Moreover, when cap 90 is engaged with container 20, the force away from container 20 due to the engagement of inner ribs 200 with outer surface 22 serves to maintain cap 90 in a position biased away from container 20 prior to release. This bias serves to inhibit easy opening of cap 90 by the user, for example a child, since this bias is in the direction of engagement of projecting members 92 with locking members 100. More particularly, the bias maintains projecting members 92 in a position such that they may not pass second end 140 of angled flange 110 wherein such passage would allow release of cap 90 from container 20.

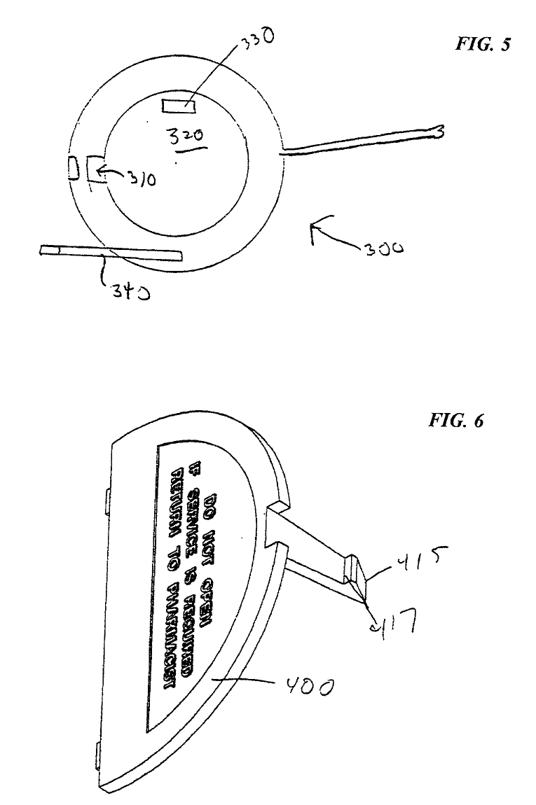

System 10 may be adapted to engage a data sending unit to allow voice instruction information to be sent to interface port 70 from such a sending unit. For example, container 20 may be received in a receiving recess 320 of recorder unit 300, as depicted in FIGS. 4-5. The recorder may be maintained at a pharmacy for use in recording information onto the unit. Locator 50 may act as an indexer by being received in an indexing slot 310 to properly align interface port 70 with a sending interface port 330 of recorder unit 300.

Recorder unit 300 is adapted to receive system 10 to allow recorder unit 300 to transmit voice information to the microchip or other storage component of system 10. Recorder unit 300 may include a microphone 340 to allow this information to be input into a processor coupled to computer storage medium or other device to allow this voice information to be saved on the recorder unit 300 and/or transmitted to the microchip or other electronic storage portion of system 10. Alternatively, recorder unit 300 might be coupled to a computing unit (not shown) running computer speech software capable of producing voice information and transmitting it to system 10, instead of utilizing microphone 340.

It is contemplated that there could be a further embodiment of the present invention where voice information is saved to the microchip or other electronic storage device through the use of infrared technology or short-term radio signals. In this embodiment, infrared or radio receivers would be located in housing 60 and an infrared or radio transmitter would transmit the voice information from recorder unit 300.

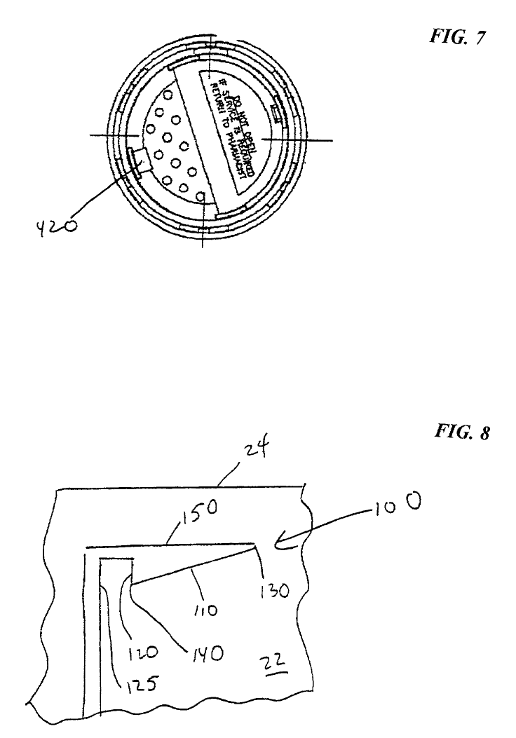

Housing 60 may also include a door 400 which is openable to allow interface port 70 to engage a sending unit port 330. Also, door 400 may be lockable to allow access to interior 55 to be limited to medical professionals, for example, pharmacists. Specifically, a locking member 415 (FIG. 6) may extend toward interior 55 from door 400 and may further include a tooth 417 (FIG. 6) which prevents door 400 from opening unless locking member 415 is elastically deformed to move tooth 417 from engagement with an engagement portion (not shown) of interior 55. For example, the engagement portion may be a protrusion (not shown) from an interior surface (not shown) of housing 60. Such elastic deformation may be performed by a key which may be inserted into a keyhole 420 (FIG. 7) and which is available only to medical professionals. By limiting such access, accidental or intentional modification of voice instructions saved via an electronic storage device of audio instruction system 10, for example, the microchip (not shown), by unqualified persons may be inhibited. For example, locking member 415 of door 400 may be openable and lockable only by a specific key, combination lock or other such means available to medical professionals, but not to the general public. As will be understood by those skilled in the art, keys and locking members may be configured in various ways to limit access to interior 55.

Housing 60 may also include a sound grid 410 (FIG. 7) which may comprise, for example, a plurality of openings in housing 60 configured to enhance clarity and quality of sound produced by sound player 30. Further, door 400 may include a warning label, as best depicted in FIG. 6, designed to discourage unauthorized personnel from tampering with interior 55 of housing 60. Yet further, as described above, interior 55 may include battery 80 coupled to sound player 30, activation member 40, and/or any electronic storage devices (not shown), etc. The openable nature of door 400 allows access to battery 80 which allows it to be removed for recycling at the end of its useful life. For example, battery 80 may be removed from system 10 before disposal of system 10 to prevent battery 80 from being sent to a landfill where it might release contaminants such as mercury. Instead, battery 80 may be recycled at the end of its life. Also, interior 55 may be accessed to replace battery 80 if battery 80 becomes inoperable.

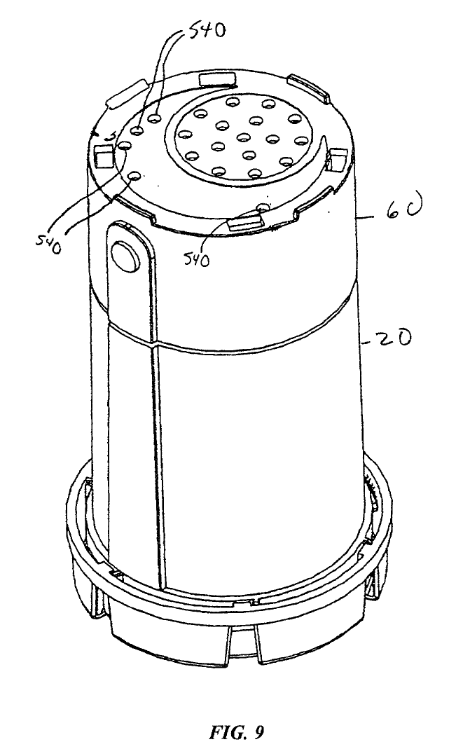

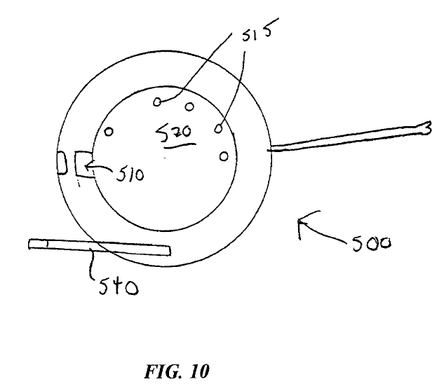

In an alternate embodiment depicted in FIG. 9, housing 60 does not include door 90, but instead includes one or more openings 540 sized to receive one or more interfacing ports or members from a recorder unit 500 (FIG.10). For example, housing 60 may include five openings to receive five projecting pins 515 located on a bottom surface of an interior portion 520 of recorder unit 500, as depicted in FIG. 10. In this example, each pin projecting from the interior may be aligned to engage or contact its proper receiving port inside housing 60 (FIG. 9) due to the ability of locator 50 (FIG. 9) to engage slot 510 thus aligning system 10 in a proper position for the engagement of pins 515 with respective openings 540 (FIG. 9). Thus, recording voice information on the device is restricted to those having access to a compatible sending unit (i.e. recorder unit 500). Specifically, such a unit would have to include projecting pins in proper locations adapted to interface with corresponding receiving ports located inside housing 60 (i.e., in interior 55). This is readily facilitated through the use of recorder unit 500, as depicted in FIG. 10, but it is contemplated that it would be available only to medical professionals. Further, any tampering or attempt to erase or re-record voice instruction information would be deterred by the inaccessibility of the receiving ports inside housing 60, as depicted in FIG. 9. Specifically, the ports are accessible solely through openings 540.

Container 20 and housing 60 may be formed of dense polyurethane, for example. Also, container 20 could be adapted to meet Consumer Product Safety Commission senior adult use requirements, as will be understood by those skilled in the art. Further, container 20 may be configured to meet United States Pharmacopeia “light and tight” requirements, as will be understood by those skilled in the art. Moreover, container 20 may be formed in various shapes and sizes to accommodate varying volumes and amounts of medicine or other materials. Such containers may be attached to housings which may be formed such that they are interchangeable to facilitate selection by a pharmacist or other medical professional.

However, when a housing and container are connected to one another it is preferable that they are not adapted to be easily separated. Such non-releaseable construction may prevent mixing of containers holding medicines which do not correspond to voice instructions recorded on a microchip or other electronic storage medium contained in various housings. Further, it will be evident to one skilled in the art that the audio instruction system of the present invention is designed for single-use only. This is particularly important when container 20 is utilized to hold medicines since refilling container 20 with a different medicine could cause cross-contamination of container 20 which might result in the user ingesting materials from an unknown previous contents of container 20, which could be harmful to him. Discouraging reuse of the device is the fact that voice information can be saved onto the micro-chip or other storing means only by a person possessing a key to open housing 60 and/or means for sending voice instruction information to one or more receiving ports 70 to allow sound player 30 to play the voice instruction information. Such voice instruction information could include prescription information such as the name of the medication, quantity, dosage instructions, name of a doctor, and name of the pharmacy which dispensed the prescription.

Further, it will be understood by one skilled in the art that system 10 might be massed produced and automated and could have voice instruction information pre-programed on the micro-chip. Also, it will be understood by those skilled in the art that locator 50 could be formed in various shapes and sizes to allow a visually impaired used to find locator 50 and activating means 40.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

In the claims:

1. An audio instruction system comprising:
a pill container;
a sound player operatively engaged to said pill container;
an activating member operatively engaged to said pill container to activate said sound player; and
a locator positioned relative to said pill container and said activating member to aid a user to locate said activating member.

2. The system of claim 1 wherein said locator comprises a locating ridge on an outer surface of said container.

3. The system of claim 1 wherein said locator comprises a depression on an outer surface of said container.

4. The system of claim 1 wherein said locator is aligned in a substantially longitudinal direction relative to said container.

5. The system of claim 1 wherein said locator comprises an aperture for receiving said activating member.

6. The system of claim 1 wherein said activating member protrudes from a surface of said container a distance substantially different from a distance said locator protrudes from said surface of said container.

7. The system of claim 1 further comprising a housing for holding said sound player, said housing connected to said container.

8. The system of claim 7 wherein said locator comprises a container ridge and said housing comprises a housing ridge substantially aligned with said container ridge.

9. The system of claim 8 wherein said housing ridge comprises an aperture for receiving said activating member.

10. The system of claim 7 wherein said sound player further comprises an interface port for receiving sound information.

11. The system of claim 10 wherein said housing comprises an interior portion and said interface port is located in said interior portion.

12. The system of claim 11 wherein said interface port comprises one of a plurality of interface ports located in said interior portion, and wherein said housing further comprises a plurality of apertures aligned with said plurality of interface ports to allow said plurality of interface ports to receive said sound information.

13. The system of claim 11 wherein said housing further comprises a door for accessing said interior portion.

14. The system of claim 1 further comprising a child-resistant cap releasably attachable to said container.

15. The system of claim 14 wherein said cap comprises a plurality of internally projecting members and said container comprises a plurality of receiving members, wherein said internally projecting members are adapted to project radially toward an axis of said cap for engaging said plurality of receiving members.

16. The system of claim 15 wherein said plurality of internally projecting members are adapted to engage said plurality of receiving members in response to said cap being turned to close said cap on said container.

17. The system of claim 16 wherein said receiving members are adapted to inhibit an opening of said cap.

18. The system of claim 17 wherein said receiving members are adapted to release said plurality of projecting members in response to a force placed on said cap toward said container to release said cap from said container.

19. The system of claim 14 wherein said cap comprises a plurality of inner ribs projecting from a bottom surface of said cap.

20. The system of claim 19 wherein said plurality of inner ribs is adapted to engage with an outer surface said container and wherein said plurality of inner ribs is adapted to elastically deform to allow the engaging.

21. The system of claim 20 wherein the elastically deforming biases said cap in a direction substantially opposite to the engaging.

22. The system of claim 1 wherein said sound player further comprises at least one interface port for receiving sound information and the system further comprises a sound information sending unit having a sending unit interface port adapted to engage said at least one interface port.

23. The system of claim 22 wherein said locator is adapted to engage said sound information sending unit to orient said at least one interface port and said sound information sending unit to allow said sound information to be received by said interface port.

24. The system of claim 23 wherein said sound information sending unit comprises an indexing slot and said locator is adapted to be received in said slot for said orienting.

25. The system of claim 1 wherein said sound player is adapted to play voice instruction information relating to contents of said pill container.

26. A method for providing audio instructions comprising;
positioning a locator on a pill container of an audio instruction device; and
feeling the locator to find an activating member for activating a sound player of the audio instruction device.

27. The method of claim 26 further comprising activating the activating member to cause the sound player to play voice instruction information relating to contents of the container.

28. The method of claim 26 wherein the locator comprises a ridge on an outer surface of a medicine container of the device.

29. A method for providing audio instructions to a user of medication, the method comprising engaging a locator of an audio instruction device with a receiving slot of an audio instruction sending unit.

30. The method of claim 29 further comprising engaging a receiving interface port of the device with a sending interface port of the audio instruction sending unit.

31. The method of claim 30 wherein the engaging aligns an aperture of the device with the sending interface port of the audio instruction sending unit to allow the engaging of the receiving interface port of the device with the sending interface port of the audio instruction sending unit.

32. The method of claim 31 further comprising opening an access door of the audio instruction device to allow the receiving interface port of the device to engage the sending interface port of the audio instruction sending unit.

33. The method of claim 30 further comprising sending voice prescription information to the audio instruction device from the audio instruction sending unit.

34. A method for providing audio instructions, said method comprising;
providing a pill container;
operatively engaging a sound player to the pill container;
operatively engaging an activating member for activating the sound player to the pill container; and
positioning a locator relative to the pill container and the activating member to aid a user to locate the activating member.
